(19) United States
(12) Patent Application Publication
(10) Pub. No.: US 2013/0114323 A1
(43) Pub. Date: May 9, 2013

(54) SEMICONDUCTOR DEVICE AND DATA STORAGE APPARATUS

(71) Applicants: Koichiro Shindo, Kawasaki-shi (JP); Masaji Iwamoto, Yokohama-shi (JP)

(72) Inventors: Koichiro Shindo, Kawasaki-shi (JP); Masaji Iwamoto, Yokohama-shi (JP)

(73) Assignee: KABUSHIKI KAISHA TOSHIBA, Tokyo (JP)

(21) Appl. No.: 13/599,181

(22) Filed: Aug. 30, 2012

(30) Foreign Application Priority Data
Aug. 31, 2011 (JP) P2011-190021

(51) Int. Cl. H01L 25/065; G11C 5/06

(52) U.S. Cl. CPC H01L 25/0657; G11C 5/06
USPC 365/63; 257/777

(57) ABSTRACT

A semiconductor device according to an embodiment includes: a rectangular substrate having a first and a second principal surfaces ; a first semiconductor chip; one or more second semiconductor chips; and one or more third semiconductor chips. The substrate has first connection terminals connected to electrodes of the one or more second semiconductor chips, and third connection terminals electrically connected to the first connection terminals and connected to first electrodes of the first semiconductor chip, on a side of a first edge on the first principal surface. The substrate has second connection terminals connected to second electrodes of the one or more third semiconductor chips, and fourth connection terminals electrically connected to the second connection terminals and connected to electrodes of the first semiconductor chip, on a side of a second edge facing the first edge across the first semiconductor chip on the first principal surface.

### CROSS-REFERENCE TO RELATED APPLICATION

This application is based upon and claims the benefit of priority from the prior Japanese Patent Application No. 2011-190021, filed on Aug. 31, 2011; the entire contents of which are incorporated herein by reference.

### BACKGROUND

Embodiments described herein relate generally to a semiconductor package in which a plurality of semiconductor chips are stacked.

Some conventional semiconductor packages have a plurality of memory chips and a control chip controlling writing and reading data to/from the memory chips built therein in which the plurality of memory chips are divided into a plurality of segments (for example, two segments) and the writing and reading data to/from the memory chips is controlled for each of the segments. In almost all of the conventional semiconductor packages, the plurality of memory chips are stacked on a mounting substrate and the control chip is disposed beside the memory chips or the control chip is disposed at a corner on the stacked memory chips.

### BRIEF DESCRIPTION OF THE DRAWINGS

FIG. 1 is a plan view of a semiconductor device according to a first embodiment.

FIG. 2A and FIG. 2B are side views of the semiconductor device according to the first embodiment.

FIG. 3A and FIG. 3B are a procedure of producing the semiconductor device according to the first embodiment.

FIG. 4A and FIG. 4B are the procedure of producing the semiconductor device according to the first embodiment.

FIG. 5A and FIG. 5B are the procedure of producing the semiconductor device according to the first embodiment.

FIG. 6A and FIG. 6B are the procedure of producing the semiconductor device according to the first embodiment.

FIG. 7A and FIG. 7B are side views of a semiconductor device according to a second embodiment.

FIG. 8A and FIG. 8B are side views of a semiconductor device according to a third embodiment.

FIG. 9A and FIG. 9B are side views of a semiconductor device according to a fourth embodiment.

FIG. 10 is a plan view of a semiconductor device according to a fifth embodiment.

FIG. 11A and FIG. 11B are side views of the semiconductor device according to the fifth embodiment.

### DETAILED DESCRIPTION

A semiconductor device according to an embodiment of the present invention includes a rectangular substrate having a first principal surface and a second principal surface facing the first principal surface; a first rectangular semiconductor chip mounted on the first principal surface; one or more second semiconductor chips stacked on the first semiconductor chip; and one or more third semiconductor chips stacked on the one or more second semiconductor chips.

The substrate has first connection terminals connected to electrodes of the one or more second semiconductor chips, and third connection terminals electrically connected to the first connection terminals and connected to first electrodes of the first semiconductor chip, on a side of a first edge on the first principal surface.

The substrate has second connection terminals connected to second electrodes of the one or more third semiconductor chips, and fourth connection terminals electrically connected to the second connection terminals and connected to electrodes of the first semiconductor chip, on a side of a second edge facing the first edge across the first semiconductor chip on the first principal surface.

The substrate has fifth and sixth connection terminals connected to third and fourth electrodes of the first semiconductor chip respectively on sides of third and fourth edges different from the first and second edges on the first principal surface.

The substrate has first and second external connection terminals electrically connected to the fifth and sixth connection terminals respectively at positions corresponding to the third and fourth edges on the second principal surface.

The first semiconductor chip has the first electrodes on a side of an edge corresponding to the first edge of the substrate, second electrodes on a side of an edge corresponding to the second edge of the substrate, the third electrodes on a side of an edge corresponding to the third edge of the substrate, and the fourth electrodes on a side of an edge corresponding to the fourth edge of the substrate respectively.

Hereinafter, embodiments will be described in detail referring to the drawings.

### First Embodiment

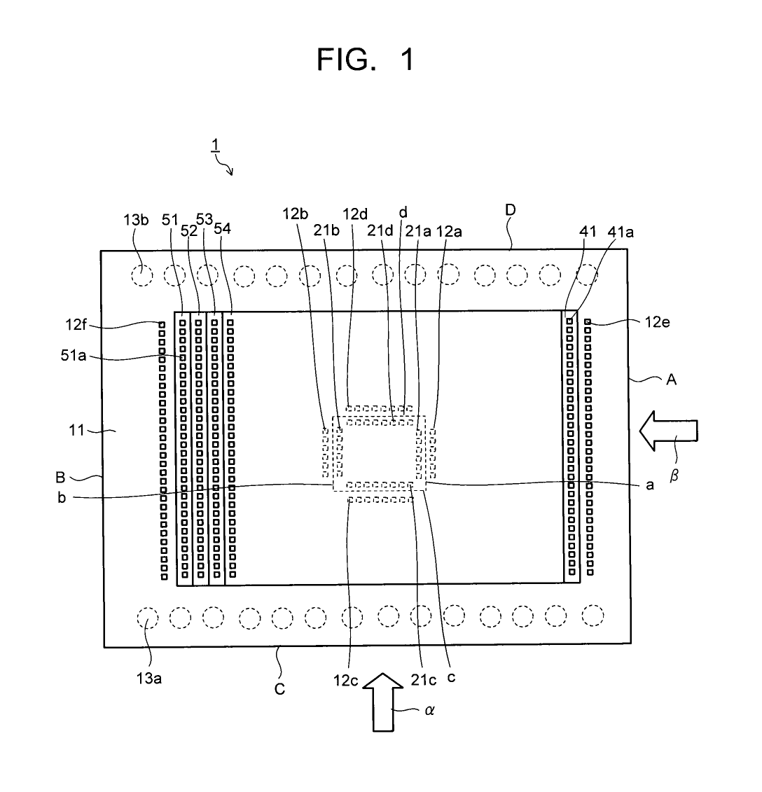

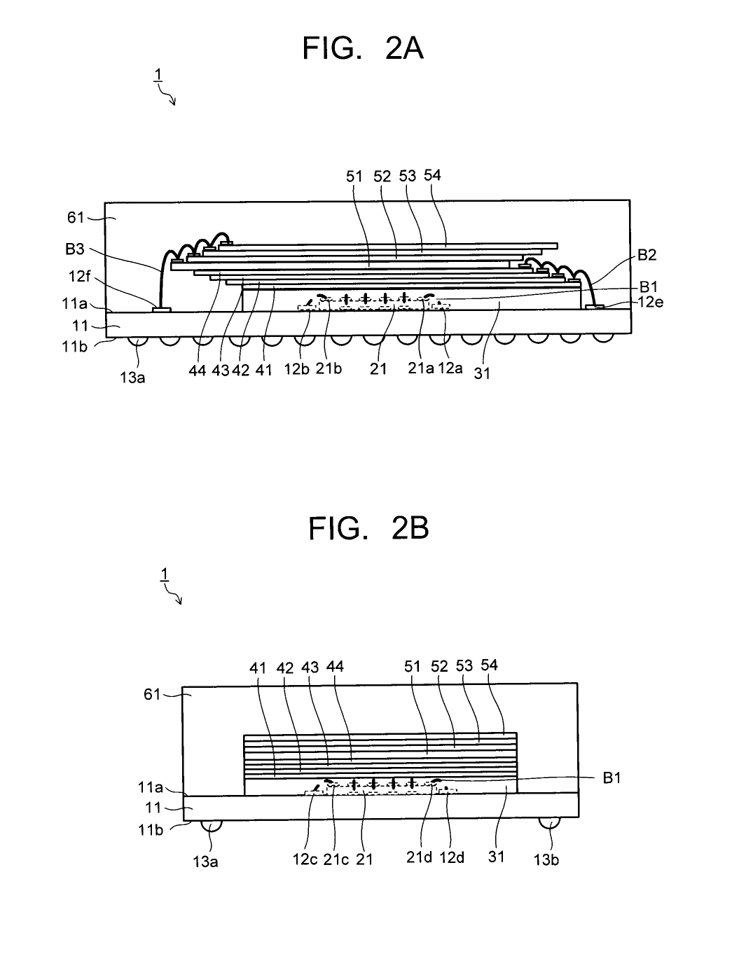

FIG. 1 is a plan view of a semiconductor device 1 according to the first embodiment. FIG. 2A and FIG. 2B are side views of the semiconductor device 1. FIG. 2A is a side view seen from the direction of an arrow α in FIG. 1. FIG. 2B is a side view seen from the direction of an arrow β in FIG. 1. Note that illustration of a sealing member 61 and bonding wires B2, B3 is omitted in FIG. 1. In FIG. 2A, the semiconductor device 1 is illustrated with the sealing member 61 seen through. In FIG. 2B, the sealing member 61 is seen through and illustration of the bonding wires B3 is omitted.

### (Outline of the Semiconductor Device 1)

First, the outline of the semiconductor device 1 will be described. The semiconductor device 1 includes a rectangular mounting substrate 11, a rectangular semiconductor chip 21, a resin layer 31, rectangular semiconductor chips 41 to 44, rectangular semiconductor chips 51 to 54, and the sealing member 61. The semiconductor chips 41 to 44 and 51 to 54 are memory chips for writing and reading data. The writing and reading data from/to the semiconductor chips 41 to 44 and 51 to 54 is performed by the semiconductor chip 21 being a control chip (controller).

In the semiconductor device 1, the writing and reading data is performed with the plurality of semiconductor chips 41 to 44 and 51 to 54 divided into two segments (first and second segments). Further, communication of data between the semiconductor chip 21 and the outside is performed also by two divided segments (third and fourth segments). In the case where the writing and reading data is performed in a divided manner by the plurality of segments as described above, if there is a difference in wiring length in each of the segments and between the segments, speeding up of the operation of the semiconductor chips is inhibited.

Hence, the semiconductor device 1 is configured such that the wiring length becomes almost the same in each of the segments and between the segments by devising the arrangement and so on of the semiconductor chip 21, the semiconductor chips 41 to 44 and the semiconductor chips 51 to 54 on the mounting substrate 11. Specifically, specific wirings (first segment) among wirings connecting the semiconductor chip 21 and the semiconductor chips 41 to 44 and specific wirings (second segment) among wirings connecting the semiconductor chip 21 and the semiconductor chips 51 to 54 are made to have almost the same wiring length. Further, specific wirings (third segment) among wirings connecting the semiconductor chip 21 and external connection terminals 13a of the mounting substrate 11 and specific wirings (fourth segment) among wirings connecting the semiconductor chip 21 and external connection terminals 13b of the mounting substrate 11 are made to have almost the same wiring length. Note that the specific wiring means a wiring used for transmitting a data signal (IO) and a timing signal designating the timing to read and write data. Hereinafter, the configuration of the semiconductor device 1 will be described. (Configuration of the semiconductor device 1)

The mounting substrate 11 has a first principal surface 11a and a second principal surface 11b corresponding to the front surface and the rear surface respectively. The mounting substrate 11 is a rectangular substrate having first to fourth edges (side surfaces) A to D. On the first principal surface 11a of the mounting substrate 11, connection terminals 12a to 12d to the semiconductor chip 21 are formed on the sides of the first to fourth edges A to D respectively. On the first principal surface 11a of the mounting substrate 11, connection terminals 12e to the semiconductor chips 41 to 44 and connection terminals 12f to the semiconductor chips 51 to 54 are formed on the sides of first and second edges A, B.

The connection terminals 12a to 12f are terminals made by non-electrolytic plating, for example, copper (Cu) terminals covered with nickel (Ni) and gold (Au). The external connection terminals 13a, 13b being connection terminals to an external substrate and the like are formed respectively on the sides of third and fourth edges C, D on the second principal surface 11b of the mounting substrate 11. The external connection terminals 13a, 13b are solder balls or solder bumps. In the mounting substrate 11, wiring layers, via holes and so on for electrically connecting the connection terminals 12a to 12f and the external connection terminals 13a, 13b are formed.

The semiconductor chip 21 controls writing and reading data from/to the semiconductor chips 41 to 44 and the semiconductor chips 51 to 54. The semiconductor chip 21 is a rectangular control chip (controller) having first to fourth edges a to d. The semiconductor chip 21 has a plurality of electrodes 21a to 21d formed along the edges a to d corresponding to the edges A to D of the mounting substrate 11 respectively. The electrodes 21a to 21d are, for example, aluminum pads. The semiconductor chip 21 is mounted on the first principal surface 11a of the mounting substrate 11. The electrodes 21a to 21d of the semiconductor chip 21 are electrically connected to the connection terminals 12a to 12d of the mounting substrate 11 respectively by bonding wires B1. The material of the bonding wire B1 is, for example, gold (Au) or copper (Cu).

The resin layer 31 embeds the semiconductor chip 21 together with the bonding wires B1. The resin layer 31 is, for example, a Film on Wire (FOW) resin. The resin layer 31 is formed on and around the semiconductor chip 21 such that its front surface (top surface) is located at a position higher than the upper ends of the bonding wires Bl. The resin layer 31 is formed such that its size (longitudinal and width) is almost the same as the size (longitudinal and width) of the rear surface of the semiconductor chip 41 stacked on its front surface (top surface).

The semiconductor chips 41 to 44 are memory chips for writing and reading data. The semiconductor chips 41 to 44 have electrodes 41a to 44a respectively on the sides of one edges on their front surfaces. The electrodes 41a to 44a are, for example, aluminum pads. The semiconductor chips 41 to 44 are stacked on the resin layer 31 with their positions being shifted such that the edges where the electrodes 41a to 44a are formed are located on the side of the edge A of the mounting substrate 11. By stacking the semiconductor chips 41 to 44 with their positions being shifted, a space for bonding to the electrodes 41a to 44a is secured.

The electrodes 41a to 44a of the semiconductor chips 41 to 44 are electrically connected to the connection terminals 12e of the mounting substrate 11 by bonding wires B2. At least a part of the electrodes 41a to 44a of the semiconductor chips 41 to 44 are electrically connected to each other by the bonding wires B2. The material of the bonding wire B2 is, for example, gold (Au) or copper (Cu).

The semiconductor chips 51 to 54 are memory chips for writing and reading data. The semiconductor chips 51 to 54 have electrodes 51a to 54a respectively on the sides of one edges on their front surfaces. The electrodes 51a to 54a are, for example, aluminum pads. The semiconductor chips 51 to 54 are stacked on the semiconductor chips 41 to 44 with their positions being shifted such that the edges where the electrodes 51a to 54a are formed are located on the side of the edge B of the mounting substrate 11. By stacking the semiconductor chips 51 to 54 with their positions being shifted, a space for bonding to the electrodes 51a to 54a is secured.

The electrodes 51a to 54a of the semiconductor chips 51 to 54 are electrically connected to the connection terminals 12f of the mounting substrate 11 by bonding wires B3. At least a part of the electrodes 51a to 54a of the semiconductor chips 51 to 54 are electrically connected to each other by the bonding wires B3. The material of the bonding wire B3 is, for example, gold (Au) or copper (Cu).

The sealing member 61 is a sealing resin (molding resin) sealing the semiconductor chip 21, the semiconductor chips 41 to 44 and the semiconductor chips 51 to 54.

### (Production of the Semiconductor Device 1)

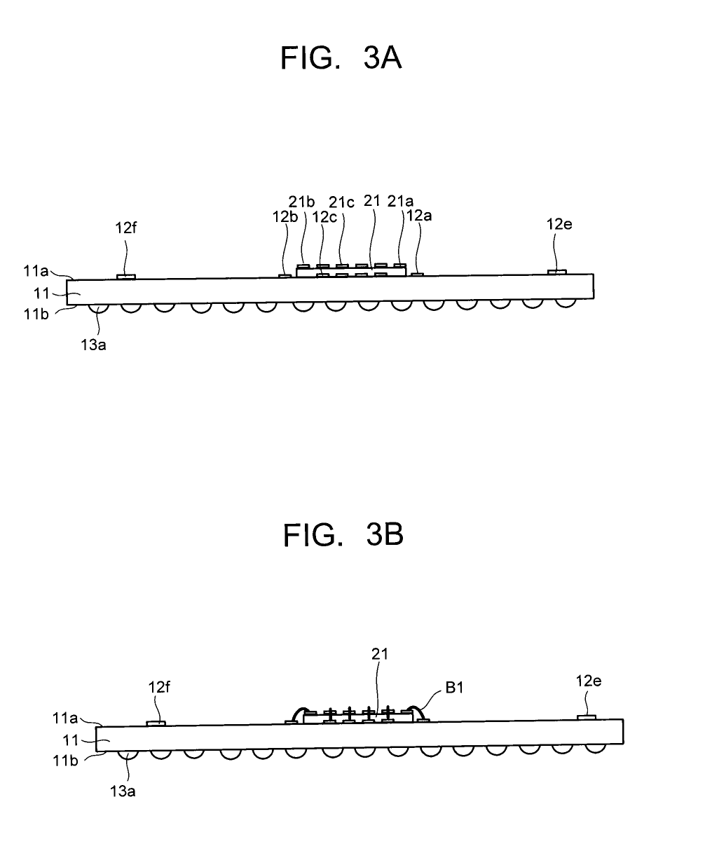

FIG. 3A to FIG. 6B are views illustrating the procedure of producing the semiconductor device 1. Hereinafter, the procedure of producing the semiconductor device 1 will be described referring to FIG. 3A to FIG. 6B. Note that the same configurations as those described in FIG. 1, FIG. 2A, and FIG. 2B are given the same numerals and overlapping description will be omitted.

### (Step 1)

The mounting substrate 11 is prepared, and the semiconductor chip 21 is mounted on the first principal surface 11a of the mounting substrate 11 (see FIG. 3A). At this moment, the semiconductor chip 21 is placed on the first principal surface 11a of the mounting substrate 11 such that the edges a to d of the semiconductor chip 21 correspond to the edges A to D of the mounting substrate 11. Note that an adhesive film is bonded on the rear surface of the semiconductor chip 21 when the semiconductor chip 21 is cut out of a semiconductor substrate (hereinafter, described as a wafer).

### (Step 2)

The connection terminals 12a to 12d of the mounting substrate 11 are connected to the electrodes 21a to 21d of the semiconductor chip 21 by the bonding wires B1 (see FIG. 3B). (Step 3)

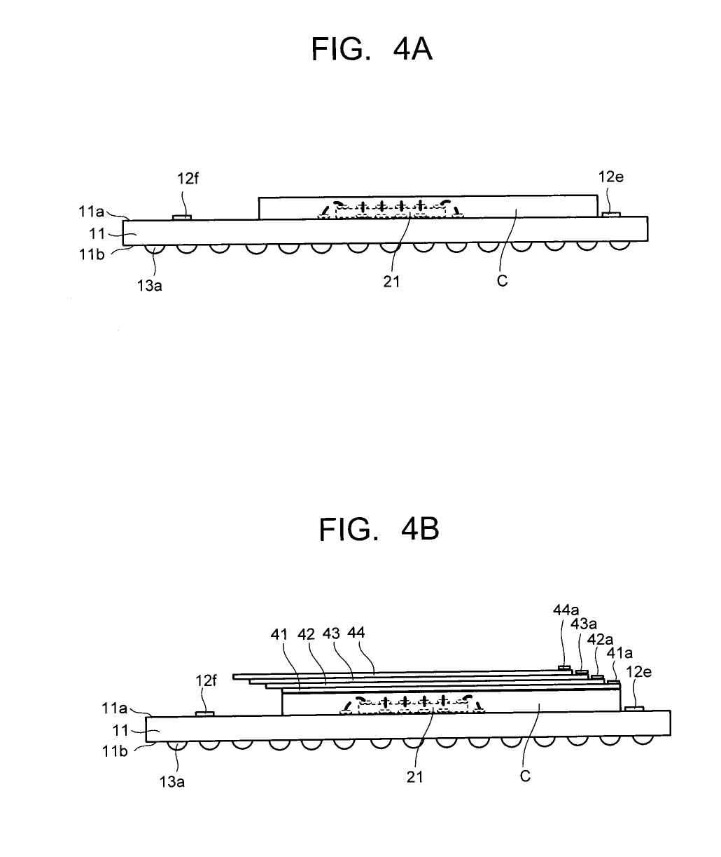

A FOW resin C which will be the resin layer 31 is applied to the front surface and the periphery of the semiconductor chip 21. The FOW resin C has a front surface (top surface) located at a position higher than the top ends of the bonding wires Bl and having almost the same size (vertical and horizontal lengths) as the size (vertical and horizontal lengths) of the rear surface of the semiconductor chip 41 stacked on the front surface (top surface) (see FIG. 4A).

### (Step 4)

In the state that the FOW resin C is semi-cured, the semiconductor chips 41 to 44 are stacked on the front surface of the FOW resin C with their positions being shifted on the rein layer 31 such that the edges where the electrodes 41a to 44a are formed are located on the side of the edge A of the mounting substrate 11 (see FIG. 4B). Note that an adhesive film is bonded on the rear surfaces of the semiconductor chips 41 to 44 when the semiconductor chips 41 to 44 are cut out of the wafer. The adhesive film, which is bonded on the rear surface of the semiconductor chip 41, can be omitted. And the FOW resin C is bonded on the rear surface of the semiconductor chip 41 when the semiconductor chip 41 is cut out of a semiconductor substrate. Then the semiconductor chip 41 is stacked on the semiconductor chip 21.

### (Step 5)

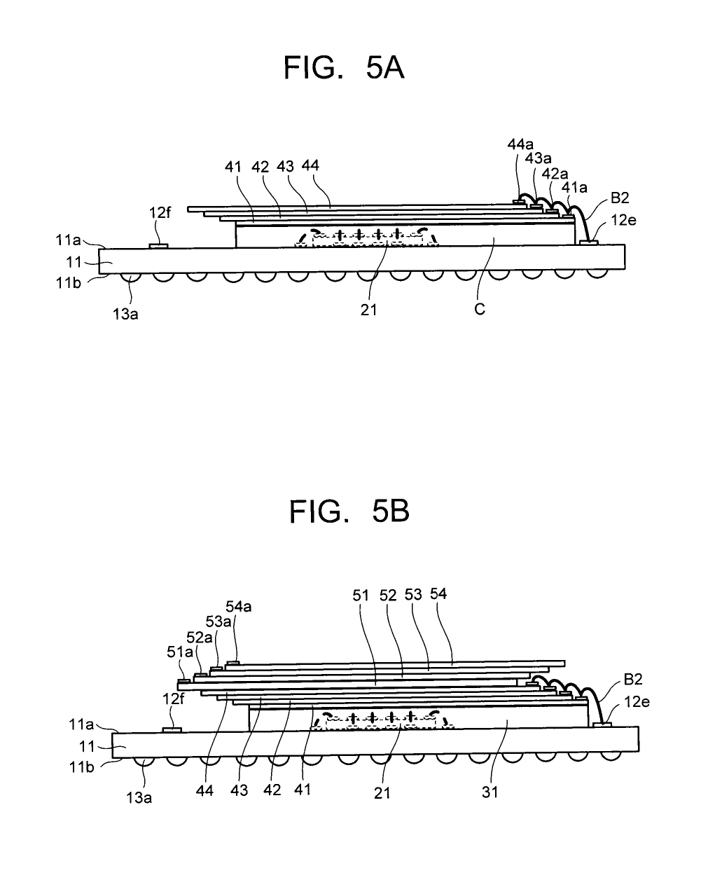

The electrodes 41a to 44a of the semiconductor chips 41 to 44 and the connection terminals 12e of the mounting substrate 11 are connected by the bonding wires B2 (see FIG. 5A). Note that the bonding may be performed by sequentially connecting from the side of the connection terminals 12e of the mounting substrate 11 to the side of the connection terminals 44a of the semiconductor chip 44. Alternatively, the bonding may be performed by sequentially connecting from the side of the connection terminals 44a of the semiconductor chip 44 to the side of the connection terminals 12e of the mounting substrate 11.

### (Step 6)

The semiconductor chips 51 to 54 are stacked on the front surface of the stacked semiconductor chip 44 with their positions being shifted such that the edges where the electrodes 51a to 54a are formed are located on the side of the edge B of the mounting substrate 11 (see FIG. 5B). Note that an adhesive film is bonded on the rear surfaces of the semiconductor chips 51 to 54 when the semiconductor chips 51 to 54 are cut out of the wafer.

### (Step 7)

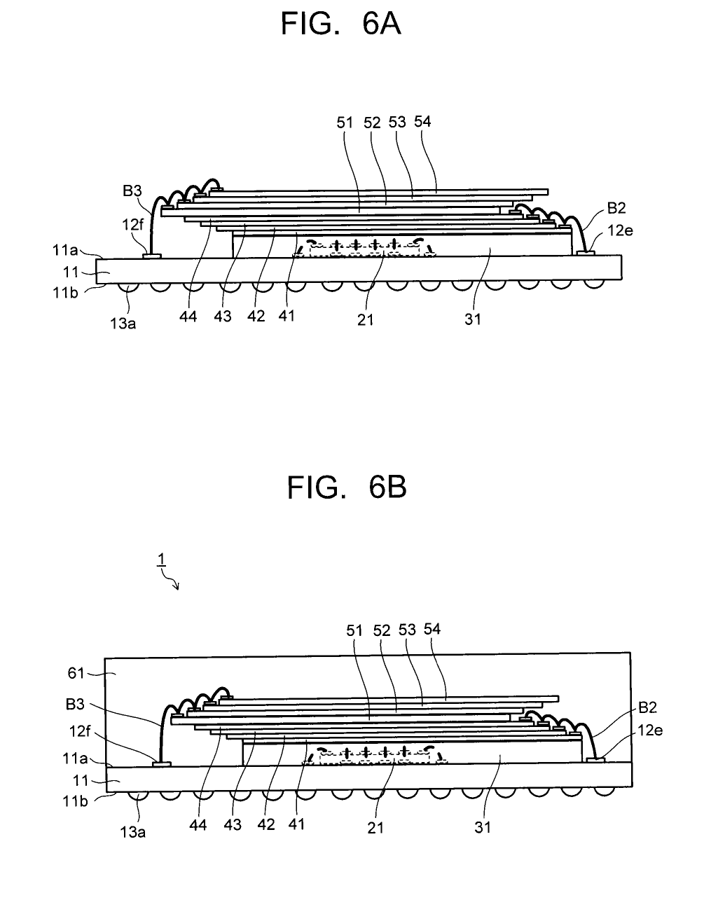

The electrodes 51a to 54a of the semiconductor chips 51 to 54 and the connection terminals 12f of the mounting substrate 11 are connected by the bonding wires B3 (see FIG. 6A). Note that the bonding may be performed by sequentially connecting from the side of the connection terminals 12f of the mounting substrate 11 to the side of the connection terminals 54a of the semiconductor chip 54. Alternatively, the bonding may be performed by sequentially connecting from the side of the connection terminals 54a of the semiconductor chip 54 to the side of the connection terminals 12f of the mounting substrate 11.

### (Step 8)

The semiconductor chip 21, the semiconductor chips 41 to 44 and the semiconductor chips 51 to 54 mounted on the first principal surface 11a of the mounting substrate 11 are sealed with a sealing resin (molding resin) being the sealing member 61 (see FIG. 6B).

The semiconductor device 1 according to the first embodiment is configured such that the semiconductor chip 21 is arranged under the rear surface of the semiconductor chip 41 to be stacked thereon. The semiconductor device 1 further has the connection terminals 12e connected to the electrodes 41a to 44a of the semiconductor chips 41 to 44 and the connection terminals 12a electrically connected to at least a part of the connection terminals 12e and connected to the electrodes 21a of the semiconductor chip 21 on the side of the first edge A on the first principal surface 11a of the mounting substrate 11, and has the connection terminals 12f connected to the electrodes 51a to 54a of the semiconductor chips 51 to 54 and the connection terminals 12b electrically connected to at least a part of the connection terminals 12f and connected to the electrodes 21b of the semiconductor chip 21 on the side of the second edge B facing the first edge A across the semiconductor chip 21 on the first principal surface 11a. Therefore, the specific wirings (first segment) among the wirings connecting the semiconductor chip 21 and the semiconductor chips 41 to 44 and the specific wirings (second segment) among the wirings connecting the semiconductor chip 21 and the semiconductor chips 51 to 54 are made to have almost the same wiring length.

The semiconductor device 1 further has the connection terminals 12c, 12d connected to the electrodes 21c, 21d of the semiconductor chip 21 respectively on the sides of the third and fourth edges C, D different from the first and second edges A, B on the first principal surface 11a of the mounting substrate 11, and has the external connection terminals 13a, 13b electrically connected to at least a part of the connection terminals 12c, 12d at positions corresponding to the third and fourth edges C, D on the second principal surface 11b of the mounting substrate 11 respectively. Therefore, the specific wirings (third segment) among the wirings connecting the semiconductor chip 21 and the external connection terminals 13a of the mounting substrate 11 and the specific wirings (fourth segment) among the wirings connecting the semiconductor chip 21 and the external connection terminals 13b of the mounting substrate 11 are made to have almost the same wiring length.

Note that the wiring lengths in the first and second segments are preferably set such that a length L₁ of the longest wiring and a length L₂ of the shortest wiring in each segment satisfy the relation of the following Expression (1).

L₂=L₁×0.8 (1)

Further, the wiring lengths between the first and second segments are preferably set such that a length L₃ of the longest wiring and a length L₄ of the shortest wiring in the first and second segments satisfy the relation of the following Expression (2).

L₄=L₃×0.8 (2)

Further, the wiring lengths in the third and fourth segments are preferably set such that a length L₅ of the longest wiring and a length L₆ of the shortest wiring in each segment satisfy the relation of the following Expression (3).

L₆=L₅×0.95 (3)

Further, the wiring lengths between the third and fourth segments are preferably set such that a length L₇ of the longest wiring and a length L₈ of the shortest wiring in the third and fourth segments satisfy the relation of the following Expression (4).

L₈=L₇×0.95 (4)

Further, it is preferable that the specific wirings (first segment) connecting the electrodes 41a to 44a of the semiconductor chips 41 to 44 and the electrodes 21a of the semiconductor chip 21 do not intersect (cross) at a middle of the path. It is also preferable that the specific wirings (second segment) connecting the electrodes 51a to 54a of the semiconductor chips 51 to 54 and the electrodes 21b of the semiconductor chip 21 do not intersect (cross) at a middle of the path.

More specifically, it is preferable that the arrangement direction of the electrodes connected to the specific wirings (first segment) among the electrodes 41a to 44a of the semiconductors 41 to 44 (memory chips) and the arrangement direction of the electrodes connected to the specific wirings (first segment) among the electrodes of the semiconductor chip 21 (controller) are the same. It is also preferable that the arrangement direction of the electrodes connected to the specific wirings (second segment) among the electrodes 51a to 54a of the semiconductors 51 to 54 (memory chips) and the arrangement direction of the electrodes connected to the specific wirings (second segment) among the electrodes of the semiconductor chip 21 (controller) are the same. For example, when the arrangement of the electrodes connected to the specific wirings (first segment) among the electrodes 41a to 44a of the semiconductor chips 41 to 44 are A, B, C, D, the arrangement of the electrodes connected to the specific wirings (first segment) among the electrodes of the semiconductor chip 21 are A, B, C, D. Note that A, B, C, D indicate the types of signals.

### Second Embodiment

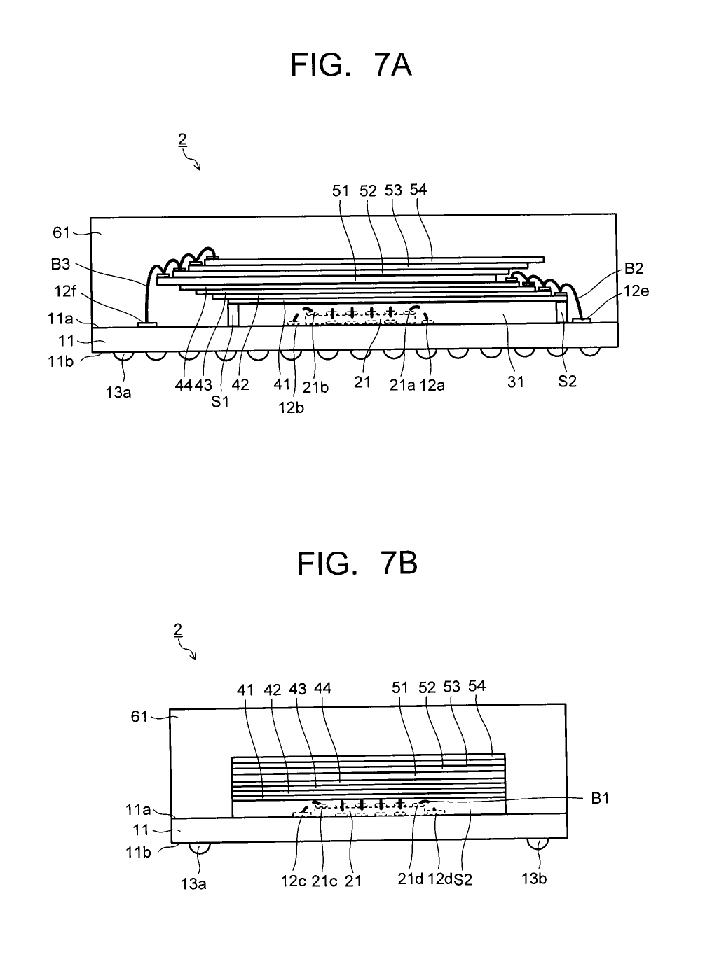

FIG. 7A and FIG. 7B are side views of a semiconductor device 2 according to the second embodiment. FIG. 7A is a side view of the semiconductor device 2 seen from the direction of the arrow α in FIG. 1. FIG. 7B is a side view of the semiconductor device 2 seen from the direction of the arrow β in FIG. 1. Note that in FIG. 7A, the semiconductor device 2 is illustrated with the sealing member 61 seen through. In FIG. 7B, the semiconductor device 2 is illustrated with the sealing member 61 seen through. Further, illustration of the bonding wires B3 is omitted in FIG. 7B. Hereinafter, the configuration of the semiconductor device 2 will be described referring to FIG. 7A and FIG. 7B. The same configurations as those of the semiconductor device 1 described referring to FIG. 1, FIG. 2A, and FIG. 2B are given the same numerals and overlapping description will be omitted.

The semiconductor device 2 according to the second embodiment further includes two spacers S1, S2 arranged along two edges facing each other on the lower surface of the semiconductor chip 41. Note that the upper ends of the two spacers S1, S2 are above the top ends of the bonding wires B1. Therefore, it is possible to prevent the semiconductor chips 41 to 44 from being stacked in a inclined state when the semiconductor chips 41 to 44 are stacked on an adhesive C in the semi-cured state which will be the resin layer 31. It is also possible to prevent the bonding wires B1 from coming into contact with the rear surface of the semiconductor chip 41. The other effects are the same as those of the semiconductor device 1 according to the first embodiment.

### Third Embodiment

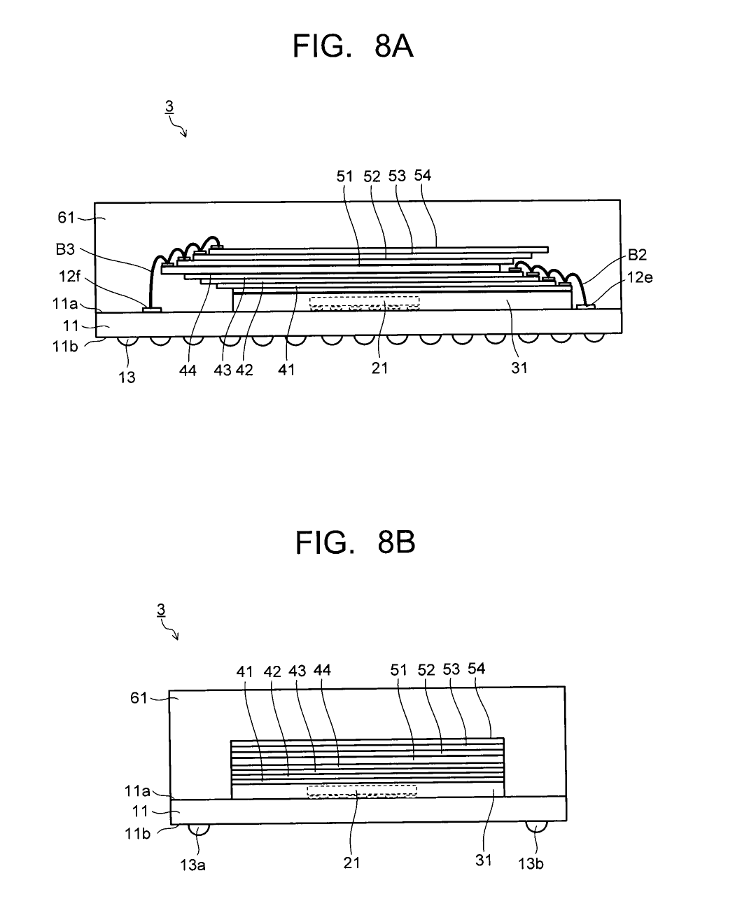

FIG. 8A and FIG. 8B are side views of a semiconductor device 3 according to the third embodiment. FIG. 8A is a side view of the semiconductor device 3 seen from the direction of the arrow α in FIG. 1. FIG. 8B is a side view of the semiconductor device 3 seen from the direction of the arrow β in FIG. 1. Note that in FIG. 8A, the semiconductor device 3 is illustrated with the sealing member 61 seen through. In FIG. 8B, the sealing member 61 is seen through and illustration of the bonding wires B3 is omitted. Hereinafter, the configuration of the semiconductor device 3 will be described referring to FIG. 8A and FIG. 8B. The same configurations as those of the semiconductor device 1 described referring to FIG. 1, FIG. 2A, and FIG. 2B are given the same numerals and overlapping description will be omitted.

The semiconductor device 3 according to the third embodiment is configured such that the upper surface of the semiconductor chip 21 is located on the lower side and the electrodes 21a of the semiconductor chip 21 are directly (without via the bonding wires B1) connected to the connection terminals 12a of the mounting substrate 11 (so called the flip-chip connection). The semiconductor device 3 according to the third embodiment is configured such that the connection height is lower than that in the case of using the bonding wires B1, so that the thickness of the semiconductor device 3 can be reduced. The other effects are the same as those of the semiconductor device 1 according to the first embodiment.

### Fourth Embodiment

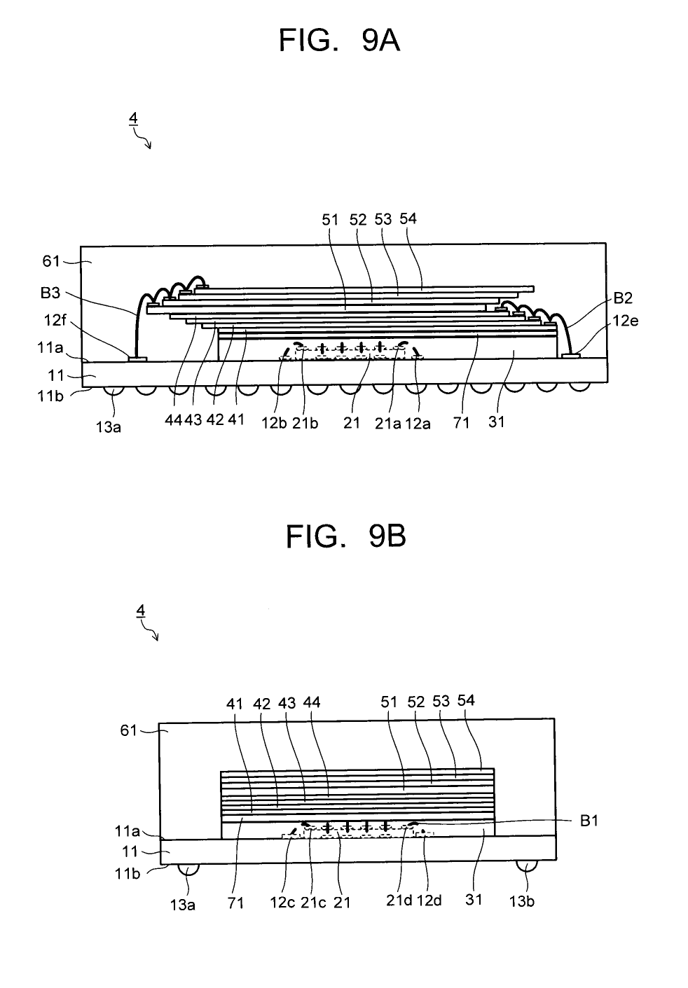

FIG. 9A and FIG. 9B are side views of a semiconductor device 4 according to the fourth embodiment. FIG. 9A is a side view of the semiconductor device 4 seen from the direction of the arrow α in FIG. 1. FIG. 9B is a side view of the semiconductor device 4 seen from the direction of the arrow β in FIG. 1. Note that in FIG. 9A, the semiconductor device 4 is illustrated with the sealing member 61 seen through. In FIG. 9B, the sealing member 61 is seen through and illustration of the bonding wires B3 is omitted. Hereinafter, the configuration of the semiconductor device 4 will be described referring to FIG. 9A and FIG. 9B. The same configurations as those of the semiconductor device 1 described referring to FIG. 1, FIG. 2A, and FIG. 2B are given the same numerals and overlapping description will be omitted.

The semiconductor device 4 according to the fourth embodiment further includes an insulating layer 71 between the resin layer 31 and the semiconductor chip 41. The insulating layer 71 can prevent the bonding wires B1 from coming into electrical contact with the rear surface of the semiconductor chip 41. The other effects are the same as those of the semiconductor device 1 according to the first embodiment.

### Fifth Embodiment

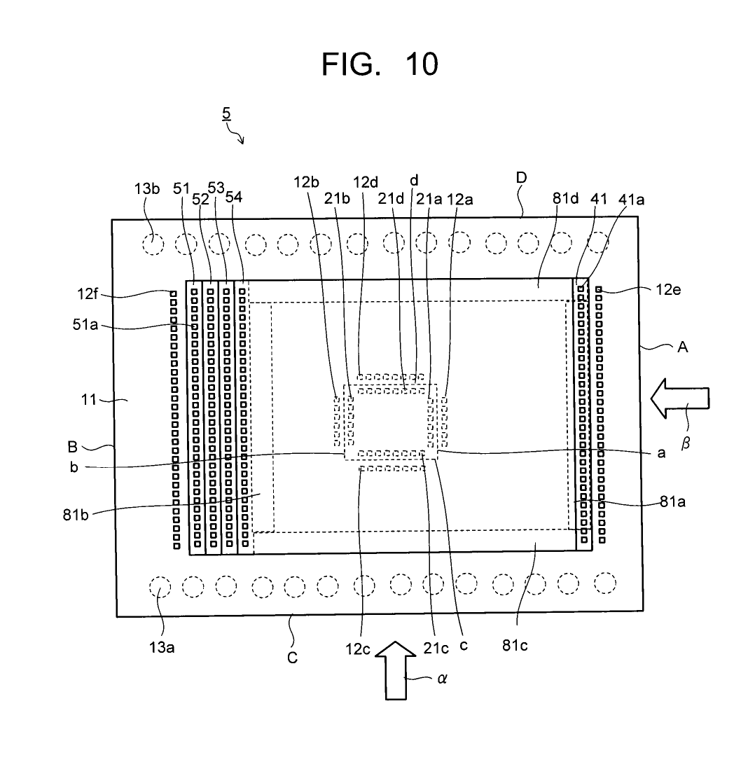

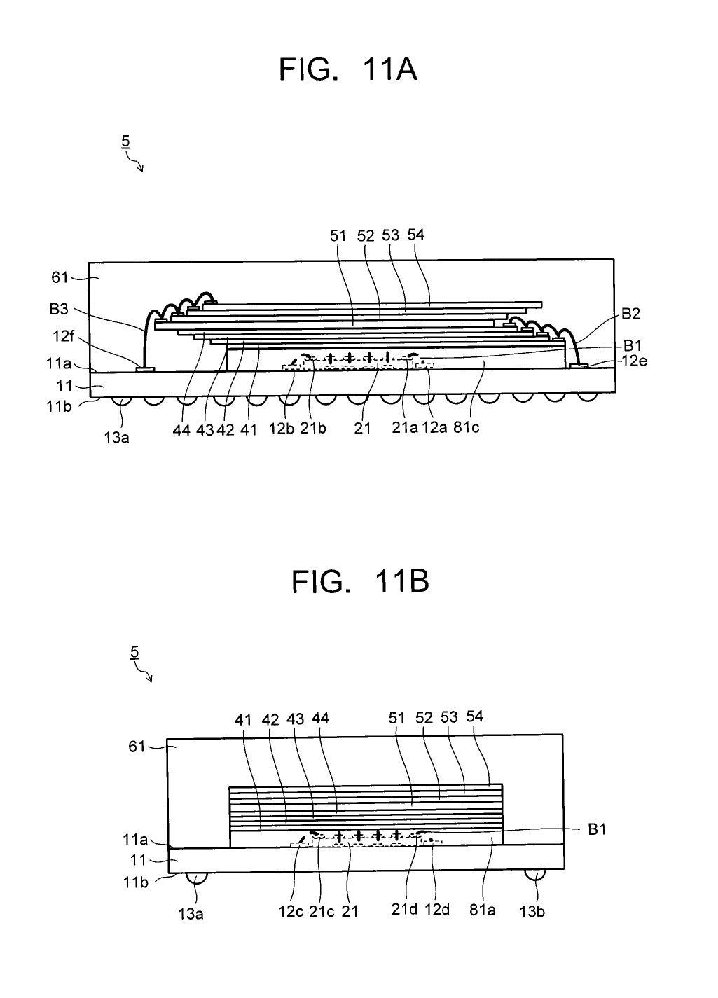

FIG. 10 is a plan view of a semiconductor device 5 according to the fifth embodiment. FIG. 11A and FIG. 11B are side views of the semiconductor device 5 according to the fifth embodiment. FIG. 11A is a side view of the semiconductor device 5 seen from the direction of the arrow α in FIG. 1. FIG. 11B is a side view of the semiconductor device 5 seen from the direction of the arrow β in FIG. 1. Note that in FIG. 11A, the semiconductor device 5 is illustrated with the sealing member 61 seen through. In FIG. 11B, the sealing member 61 is seen through and illustration of the bonding wires B3 is omitted. Hereinafter, the configuration of the semiconductor device 5 will be described referring to FIG. 11A and FIG. 11B. The same configurations as those of the semiconductor device 1 described referring to FIG. 1, FIG. 2A, and FIG. 2B are given the same numerals and overlapping description will be omitted.

The semiconductor device 5 according to the fifth embodiment includes four spacers 81a to 81d made of silicon (Si) arranged along respective edges of the semiconductor chip 41, in place of the resin layer 31, on the lower surface of the semiconductor chip 41. Note that the effects are the same as those of the semiconductor device 1 according to the first embodiment.

The wirings between the semiconductor chip 21 being the control chip (controller) and the semiconductor chips 41 to 44 and 51 to 54 being memories are divided into two segments in each of the above-described embodiments but may be divided into three or more segments. Further, the number of memory chips in one segment is not limited to four but may be an arbitrary number. Further, the wirings between the semiconductor chip 21 being the control chip (controller) and the external terminals of the mounting substrate 11 are divided into two segments but may be divided into three or more segments.

Further, the semiconductor chip is sealed with the sealing resin (molding resin) in each of the above-described embodiments, the semiconductor chip may be configured to be sealed with a casing made of metal or ceramic (for example, alumina (Al₂O₃)). These embodiments and modifications thereof fall within the scope and spirit of the inventions and similarly fall within the scope of the inventions described in claims and their equivalents.

### Other Embodiments

While certain embodiments have been described, these embodiments have been presented by way of example only, and are not intended to limit the scope of the inventions. Indeed, the novel embodiments described herein may be embodied in a variety of other forms; furthermore, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a rectangular substrate having a first principal surface and a second principal surface facing the first principal surface;
a first semiconductor chip mounted on the first principal surface;
one or more second semiconductor chips stacked on the first semiconductor chip; and
one or more third semiconductor chips stacked on the one or more second semiconductor chips,
wherein the substrate includes:
first connection terminals connected to electrodes of the one or more second semiconductor chips, and third connection terminals electrically connected to the first connection terminals and connected to first electrodes of the first semiconductor chip, on a side of a first edge on the first principal surface; and
second connection terminals connected to second electrodes of the one or more third semiconductor chips, and fourth connection terminals electrically connected to the second connection terminals and connected to electrodes of the first semiconductor chip, on a side of a second edge facing the first edge across the first semiconductor chip on the first principal surface.

2. The device according to claim 1,
wherein the substrate includes:
the fifth and sixth connection terminals connected to third and fourth electrodes of the first semiconductor chip respectively on sides of third and fourth edges different from the first and second edges on the first principal surface; and
the first and second external connection terminals electrically connected to the fifth and sixth connection terminals respectively at positions corresponding to the third and fourth edges on the second principal surface.

3. The device according to claim 2,
wherein the first semiconductor chip is rectangular and includes:
the first electrodes on a side of an edge corresponding to the first edge of the substrate; and
the second electrodes on a side of an edge corresponding to the second edge of the substrate.

4. The device according to claim 3,
wherein the first semiconductor chip includes:
the third electrodes on a side of an edge corresponding to the third edge of the substrate; and
the fourth electrodes on a side of an edge corresponding to the fourth edge of the substrate.

5. The device according to claim 4,
wherein a wiring length from the first electrode of the first semiconductor chip to the electrode of the one or more second semiconductor chips and a wiring length from the second electrode of the first semiconductor chip to the electrode of the one or more third semiconductor chips are almost the same.

6. The device according to claim 5,
wherein a wiring length from the electrode of the first semiconductor chip to the first external connection terminal and a wiring length from the electrode of the first semiconductor chip to the second external connection terminal are almost the same.

7. A data storage apparatus, comprising:
a rectangular substrate having a first principal surface and a second principal surface facing the first principal surface;
a controller mounted on the first principal surface;
one or more first semiconductor memory chips stacked on the controller; and
one or more second semiconductor memory chips stacked on the one or more first semiconductor memory chips,
wherein the substrate includes:
first connection terminals connected to electrodes of the one or more first semiconductor memory chips, and third connection terminals electrically connected to the first connection terminals and connected to first electrodes of the controller, on a side of a first edge on the first principal surface; and
second connection terminals connected to second electrodes of the one or more second semiconductor memory chips, and fourth connection terminals electrically connected to the second connection terminals and connected to electrodes of the controller, on a side of a second edge facing the first edge across the controller on the first principal surface.
